(19) United States
(12) Patent Application Publication
(10) Pub. No.: US 2026/0259835 A1
(43) Pub. Date: Sep. 3, 2026

(54) Method and Apparatus for Adjusting Timing, Computer-Readable Storage Medium and Electronic Device

(71) Applicants: Analogix (SHANGHAI) Semiconductor CO., LTD., Pudong New Area, Shanghai (CN); ANALOGIX INTERNATIONAL LLC

(72) Inventors: Pengfei ZHU, Shanghai (CN); Peng CHEN, Shanghai (CN); Junjian WANG, Shanghai (CN)

(21) Appl. No.: 18/294,547

(22) PCT Filed: Nov. 21, 2023
(86) PCT No.: PCT/CN2023/133020

§ 371 Date: Feb. 2, 2024

(30) Foreign Application Priority Data
Nov. 2, 2023 (CN) 202311453271.8

(51) Int. Cl. G06F 13/10; G06F 3/14

(52) U.S. Cl. CPC G06F 13/102; G06F 3/14

(57) ABSTRACT

The present disclosure provides a method and apparatus for adjusting timing, a computer-readable storage medium and an electronic device. The method for adjusting timing includes: in response to a data stream outputted by a transmitting end of a display port being received, determining a first line period according to the data stream, and the first line period is a line period of the data stream under an output clock, and the output clock is a clock domain of a receiving end of the display port; processing the first line period at least using a Kalman filtering algorithm to obtain a second line period, and the second line period is a line period of the data stream under a source clock, and the source clock is a clock domain of the transmitting end; and adjusting the output clock according to the second line period.

### CROSS-REFERENCE TO RELATED APPLICATION

The present disclosure claims priority to Chinese Patent Application No. 202311453271.8, filed to the China National Intellectual Property Administration on Nov. 2, 2023 and entitled “Method and Apparatus for Adjusting Timing, Computer-Readable Storage Medium and Electronic Device”, the disclosure of which is incorporated herein by reference in its entirety.

### TECHNICAL FIELD

The present disclosure relates to the technical field of data transmission, and in particular, to a method and apparatus for adjusting timing, a computer-readable storage medium and an electronic device.

### BACKGROUND

In a DP (Display Port) protocol, transmission time sequence information on a Main Link is generated according to content of image data. In a DP transmitting end, the resolution and refresh rate of the image data are fixed values, and a stable pixel clock is used to correspond to a stable line length time, so that the line length time corresponding to each row of image data is fixed. Due to the change of clock domain, when a DP receiving end restores a time sequence of the image, the line length becomes larger or smaller, and the resolution of each row cannot be kept consistent, thus resulting in distortion of an image output downstream during conversion or incorrect output of the image.

### SUMMARY

A main object of the present disclosure is to provide a method and apparatus for adjusting timing, a non-transitory computer-readable storage medium and an electronic device.

According to one aspect of the present disclosure, provided is a method for adjusting timing, including: in response to a data stream outputted by a transmitting end of a display port being received, a first line period is determined according to the data stream, and the first line period is a line period of the data stream under an output clock, and the output clock is a clock domain of a receiving end of the display port; the first line period is processed at least using a Kalman filtering algorithm to obtain a second line period, and the second line period is a line period of the data stream under a source clock, and the source clock is a clock domain of the transmitting end; and the output clock is adjusted according to the second line period.

Optionally, the first line period is determined according to the data stream includes: the data stream is restored, to obtain image data and the output clock; two adjacent identical blanking identifiers are extracted from the image data, and the blanking identifier include at least one of a blanking start identifier and a blanking end identifier; and it is determined that a clock period of the two adjacent identical blanking identifiers under the output clock as the first line period.

Optionally, the transmitting end outputs the data stream by at least one link, one of the link corresponds to at least one first First Input First Output (FIFO) queue and at least one second FIFO queue, and the first line period is processed at least using the Kalman filtering algorithm to obtain the second line period, include: the first line period is wrote into the first FIFO queue corresponding to the link according to the link corresponding to the first line period; in response to the first FIFO queue not being empty, the first line period is read from the first FIFO queue, and the first line period is inputted into a Kalman filter, so that the Kalman filter outputs a second initial line period, and the second initial line period is composed of the second line period and multiple pieces of decimal data; the second initial line period is wrote into the corresponding second FIFO queue; the second initial line period is read from the second FIFO queue, and the second initial line period is inputted into the Kalman filter for iterative calculation; and a part of the multiple pieces of decimal data in the second initial line period is truncated and superposition processing is performed on truncated decimal data, the second line period is generated according to the truncated second initial line period and an accumulated error obtained by the superposition processing, and the second line period is transmitted.

Optionally, the first line period is inputted into the Kalman filter, so that the Kalman filter outputs the second initial line period, includes: the first line period is inputted into the Kalman filter, so that the Kalman filter predicts a system state according to the first line period, so as to obtain the second initial line period, and the system state is a clock period of two adjacent identical blanking identifiers in the data stream under the source clock, and the blanking identifier include at least one of a blanking start identifier and a blanking end identifier.

Optionally, the first line period is wrote into the first FIFO queue corresponding to the link, includes: in response to a first interrupt being triggered, the first line period is wrote into the first FIFO queue corresponding to the link, and the first interrupt is ended, and the first interrupt carries an interrupt number generated according to the link and a serial number of the data stream; and the second initial line period is read from the second FIFO queue, includes: in response to a second interrupt being triggered, the second line period is read from the second FIFO queue according to a predetermined algorithm, and the second interrupt is ended, and the predetermined algorithm includes one of: a cyclic scheduling algorithm and a priority scheduling algorithm, and the second interrupt carries the interrupt number.

Optionally, the source clock is a line clock or a pixel clock, and in response to the source clock being the line clock, after the first line period is processed at least using the Kalman filtering algorithm to obtain the second line period, the method further includes: clock domain conversion is performed on the second line period, to obtain a line period of the first line period under a pixel clock; and in response to the source clock being the pixel clock, before the first line period is processed at least using the Kalman filtering algorithm to obtain the second line period, the method further includes: clock domain conversion is performed on the first line period, to obtain the line period of the first line period under the pixel clock.

Optionally, the output clock is adjusted according to the second line period includes: a dividing ratio is calculated according to the second line period and a reference clock period in a phase locked loop; and according to the dividing ratio, the phase locked loop is controlled to generate a corresponding adjustment clock signal so as to restore at least one of: a phase of the output clock and a frequency of the output clock.

According to another aspect of the present disclosure, provided is an apparatus for adjusting timing, including: a determination component, configured to in response to a data stream outputted by a transmitting end of a display port being received, determine a first line period according to the data stream, and the first line period is a line period of the data stream under an output clock, and the output clock is a clock domain of a receiving end of the display port; a processing component, configured to process the first line period at least using a Kalman filtering algorithm to obtain a second line period, and the second line period is a line period of the data stream under a source clock, and the source clock is a clock domain of the transmitting end; and an adjustment component, configured to adjust the output clock according to the second line period.

According to still another aspect of the present disclosure, provided is a non-transitory computer-readable storage medium, the non-transitory computer-readable storage medium including a program stored therein, and when the program runs, a device where the non-transitory computer-readable storage medium is located is controlled to execute any one of the method.

According to yet another aspect of the present disclosure, provided is an electronic device, including: one or more processors, a memory and one or more programs, and the one or more programs are stored in the memory and configured to be executed by the one or more processors, and the one or more programs include instructions for executing any one of the methods.

### BRIEF DESCRIPTION OF THE DRAWINGS

The drawings of the description, constituting a part of the present disclosure, are used for providing further understanding of the present disclosure, and the illustrative embodiments of the present disclosure and illustrations thereof are used for explaining the present disclosure, rather than constitute inappropriate limitation on the present disclosure. In the drawings:

FIG. 1 shows a structural block diagram of hardware of a mobile terminal for executing a method for adjusting timing provided according to embodiments of the present disclosure;

FIG. 2 shows a schematic flowchart of a method for adjusting timing provided according to embodiments of the present disclosure;

FIG. 3 shows a schematic diagram of an implementation structure of Kalman filtering software and hardware provided according to embodiments of the present disclosure;

FIG. 4 shows a schematic flowchart of a Kalman filtering algorithm provided according to embodiments of the present disclosure;

FIG. 5 shows a workflow diagram of a first FIFO queue provided according to embodiments of the present disclosure;

FIG. 6 shows a workflow diagram of a second FIFO queue provided according to embodiments of the present disclosure;

FIG. 7 shows a schematic diagram of adjusting timing at a receiving end provided according to embodiments of the present disclosure;

FIG. 8 shows another schematic diagram of adjusting timing at a receiving end provided according to embodiments of the present disclosure;

FIG. 9 shows a schematic flowchart diagram of adjusting timing provided according to embodiments of the present disclosure; and

FIG. 10 shows a structural block diagram of an apparatus for adjusting timing provided according to embodiments of the present disclosure.

The drawings include the following reference signs:
102. Processor; 104. Memory; 106. Transmission device; 108. Input/output device.

### DETAILED DESCRIPTION OF THE EMBODIMENTS

It is to be noted that embodiments in the present disclosure and features in the embodiments may be combined with one another without conflicts. Hereinafter, the present disclosure is described in detail with reference to the accompanying drawings and in conjunction with the embodiments.

In order to enable a person skilled in the art to understand the solutions of the present disclosure better, hereinafter, the technical solutions in the embodiments of the present disclosure will be described clearly and thoroughly with reference to the accompanying drawings of embodiments of the present disclosure. Obviously, the embodiments as described are only some of embodiments of the present disclosure, and are not all the embodiments. On the basis of the embodiments in the present disclosure, all other embodiments obtained by a person of ordinary skill in the art without any inventive effort shall all fall within the scope of protection of the present disclosure.

It should be noted that the terms “first”, “second” etc. in the description, claims, and accompanying drawings of the present disclosure are used to distinguish similar objects, and are not necessarily used to describe a specific sequence or order. It should be understood that the data so used may be interchanged where appropriate, so that embodiments of the present disclosure described herein can be implemented in sequences other than those illustrated or described herein. In addition, terms “include” and “have” and any variations thereof are intended to cover a non-exclusive inclusion, for example, a process, method, system, product or device which includes a series of steps or components is not necessarily limited to those steps or components that are clearly listed, but may include other steps or components that are not clearly listed or inherent to these process, method, product, or device.

As introduced in the Background, in the related art, as the clock frequency of a DP transmitting end does not match that of a DP receiving end, image data restored by the DP receiving end is distorted or even cannot be normally outputted. To solve the technical problem, embodiments of the present disclosure provide a method and apparatus for adjusting timing, a non-transitory computer-readable storage medium and an electronic device.

The technical solutions in the embodiments of the present disclosure will be clearly and completely described below with reference to the accompanying drawings in the embodiments of the present disclosure.

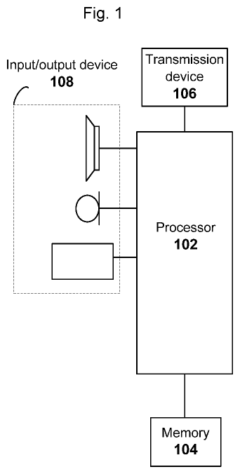

The method embodiments provided in the embodiments of the present disclosure can be executed in a mobile terminal, a computer terminal or a similar computing apparatus. Taking the method embodiments being executed on a mobile terminal as an example, FIG. 1 is a structural block diagram of hardware of a mobile terminal for a method for adjusting timing according to embodiments of the present disclosure. As shown in FIG. 1, a mobile terminal may include: one or more (FIG. 1 shows only one) processors 102 (the processors 102 may include, but not limited to processing apparatus such as a micro processor, MCU or a programmable logic device, FPGA); and a memory 104 for storing data, and the mobile terminal can further include a transmission device 106 and an input/output device 108 for communication functions. A person of ordinary skill in the art would understand that the structure as shown in FIG. 1 is merely exemplary, and does not limit the structure of the mobile terminal. For example, the mobile terminal may also include more or fewer assemblies than those shown in FIG. 1, or have different configuration from that shown in FIG. 1.

The memory 104 may be used for storing a computer program, for example, a software program and module of application software, such as a computer program corresponding to the method for adjusting timing in embodiments of the present disclosure; and the processor 102 executes various functional applications and data processing by running the computer program stored in the memory 104, i.e. implementing the described method. The memory 104 may include a high-speed random access memory, and may also include a non-transitory memory, such as one or more magnetic storage apparatuses, flash memories or other non-transitory solid-state memories. In some examples, the memory 104 may further include memories remotely arranged with respect to the processors 102, and these remote memories may be connected to the mobile terminal via a network. Examples of the network include, but are not limited to the Internet, an intranet, a local area network, a mobile communication network and combinations thereof. The transmission apparatus 106 is used to receive or send data via a network. Specific examples of the network may include a wireless network provided by a communication provider of the mobile terminal. In one example, the transmission apparatus 106 includes a network adapter (Network Interface Controller, NIC for short) which may be connected to other network devices by means of a base station, thereby being able to communicate with the Internet. In one example, the transmission apparatus 106 may be a Radio Frequency (RF for short) module which is configured to communicate with the Internet in a wireless manner.

In this embodiment, a method for adjusting timing running in a mobile terminal, a computer terminal, a processor or a similar computing apparatus is provided. It should be noted that the steps illustrated in the flowchart of the drawings can be executed in a computer system such as a set of computer-executable instructions, and although a logical order is shown in the flowchart, in some cases, the steps shown or described can be executed in a different order from that described herein.

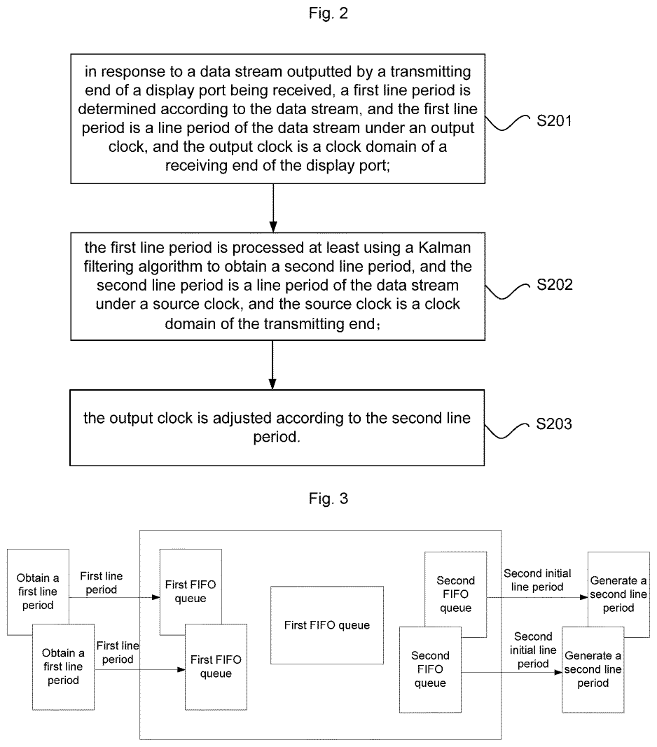

FIG. 2 is a flowchart of a method for adjusting timing according to embodiments of the present disclosure. As shown in FIG. 2, the method includes the following steps.

Step S201, in response to a data stream outputted by a transmitting end of a display port being received, a first line period is determined according to the data stream, and the first line period is a line period of the data stream under an output clock, and the output clock is a clock domain of a receiving end of the display port.

Specifically, the line period is the time required for scanning one row of pixels, i.e. the number of pixels in one row, and is also referred to as a line length. Driven by the output clock, the receiving end samples a received signal to restore a pixel clock matching the clock of the transmitting end, thereby restoring accurate data. Generally, the receiving end samples the received signal at a rising edge or falling edge of the output clock. A clock domain of the receiving end is generally a line clock.

Step S202, the first line period is processed at least using a Kalman filtering algorithm to obtain a second line period, and the second line period is a line period of the data stream under a source clock, and the source clock is a clock domain of the transmitting end.

Specifically, the clock domain of the source clock is usually a main link domain.

Step S203, the output clock is adjusted according to the second line period.

By the embodiments, firstly according to the data stream transmitted by the transmitting end of the display port, the first line period of the data stream under the output clock is determined; then the first line period is processed at least using the Kalman filtering algorithm, to obtain the second line period of the data stream under the source clock; and finally, the output clock is adjusted according to the obtained second line period. Compared with the problem in the related art that the clock frequency of a DP transmitting end does not match that of a DP receiving end, image data restored by the DP receiving end is distorted or even cannot be normally outputted, in the present disclosure, according to the first line period, the second line period is predicted and estimated at least using the Kalman filtering algorithm, to obtain the second line period which stably reflects a pixel line length of the transmitting end, and then the estimated second line period is used to adjust the output clock, ensuring that the frequency of the adjusted output clock substantially matches the frequency of the source clock, thereby ensuring that image data restored according to the adjusted output clock is substantially consistent with original data, and avoiding the problem that the restored image data is distorted or even cannot be normally outputted.

In some optional embodiments, the first line period is determined according to the data stream includes: the data stream is restored, to obtain image data and the output clock; two adjacent identical blanking identifiers are extracted from the image data, and the blanking identifier include at least one of a blanking start (BS for short) identifier and a blanking end (BE for short) identifier; and it is determined that a clock period of the two adjacent identical blanking identifiers under the output clock as the first line period.

In the embodiments, firstly the received data stream is restored to obtain the output clock and the image data including blanking identifiers, then the number of clock periods of two adjacent blanking start identifiers or two adjacent blanking end identifiers under the output clock is used to measure the line length of the image data, so as to obtain the first line period, which can obtain the first line period corresponding to the data stream more accurately, thereby providing more accurate data support for subsequent estimation of the second line period.

Specifically, the image data generally includes a BS identifier, a field blanking identifier, a timer value, a virtual display, a BE identifier, pixel data, a filling start identifier, filling data and a filling end identifier.

In some exemplary embodiments, the first line period is processed at least using the Kalman filtering algorithm to obtain the second line period, includes: the first line period is processed using the Kalman filtering algorithm, to obtain a system state representing a clock period of two adjacent identical blanking identifiers in the data stream under the source clock, and the system state is the second line period.

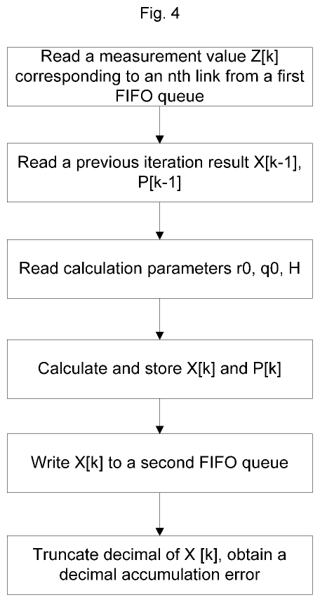

Of course, in addition to the embodiments, a person skilled in the art may also use other manners to determine the second line period. In the present disclosure, the transmitting end outputs the data stream by at least one link, that is to say, the transmitting end transmits the data stream by a single-stream transport (SST for short) mode or a multi-stream transport (MST for short) mode, and one of the link corresponds to at least one first FIFO queue and at least one second FIFO queue. As shown in FIGS. 3 and 4, step S202: the first line period is processed at least using the Kalman filtering algorithm to obtain the second line period, includes the following specific steps.

Step S2021: the first line period is wrote into the first FIFO queue corresponding to the link according to the link corresponding to the first line period.

Specifically, the link corresponding to the first line period is a link for transmitting the data stream of the first line period. The first FIFO queue and the second FIFO queue may be hardware-designed FIFO or software-designed FIFO.

Step S2022: in response to the first FIFO queue not being empty, the first line period is read from the first FIFO queue, and the first line period is inputted into a Kalman filter, so that the Kalman filter outputs a second initial line period, and the second initial line period is composed of the second line period and multiple pieces of decimal data.

Specifically, the Kalman filter is used for executing the Kalman filtering algorithm, and may be a hardware-designed device or a software-designed device; and the second initial line period is an original period value of the data stream under the source clock, the original period value being estimated by the Kalman filtering algorithm, and the second initial line period is a decimal number. The decimal data is a decimal part value of the second initial line period.

Step S2023: the second initial line period is wrote into the corresponding second FIFO queue;
step S2024: the second initial line period is read from the second FIFO queue, and the second initial line period is inputted into the Kalman filter for iterative calculation.

Specifically, the Kalman filtering algorithm is to obtain an optimal estimation value of a system state at the current moment of a dynamic system by a system state at a previous moment and a measurement value at the current moment; therefore, after the second initial line period is obtained, the second initial line period needs to be then fed back to an input end of the Kalman filter.

Step S2025: a part of the decimal data in the second initial line period is truncated and superposition processing is performed on truncated decimal data, the second line period is generated according to a truncated second initial line period and an accumulated error obtained by the superposition processing, and the second line period is transmitted.

Specifically, since the Kalman filtering algorithm is a cyclic iterative algorithm, the Kalman filtering algorithm performs truncation once every time when one second line period is obtained, and correspondingly obtains one piece of truncated decimal data, and obtains an accumulated error by performing superposition processing on these truncated decimal data.

In the embodiments, dynamic filtering is performed on the first line period by the Kalman filtering algorithm, so that it can be further ensured that the second line period which stably reflects a pixel line length of a transmitting end is obtained, further achieving time sequence adjustment on a receiving end, thereby further ensuring that the restored image data at the receiving end is accurate and reliable. Furthermore, the Kalman filtering algorithm is an iterative algorithm, and needs to calculate a system state at the current moment according to a system state calculated at a previous moment and a measurement value at the current moment; therefore, in the present disclosure, by providing two stages of FIFO queues, the difference between a measurement value interval and a system state interval can be balanced, so that the two are basically the same, thereby further facilitating execution of the Kalman filtering algorithm. Furthermore, in the present disclosure, a first FIFO queue and a second FIFO queue are allocated for a transmission link of each data stream, so that a plurality of transmission links share Kalman filtering calculation resources, and data stream iterative calculation of various links is executed in a time division manner, so that the second line period corresponding to each link can be obtained, thereby avoiding the problem of resource waste caused by designing independent calculation resource for each link.

Of course, by providing the first FIFO queue and the second FIFO queue, the problem of losing multi-link data in an inputting and outputting process can also be prevented, and frequent bus operations can be avoided, thereby reducing the burden of a processor.

In order to further ensure the flexibility of time sequence adjustment, in an optional embodiment, the Kalman filter is a device for implementing the Kalman filtering algorithm, and the first FIFO queue and the second FIFO queue are software-implemented. Compared with a hardware-only implementation manner, the implementation manner of combining software and hardware in the present disclosure can provide the capability of programmable modification and updating a dynamic filtering algorithm in subsequent stages.

In addition, the second line period is generated according to the truncated second initial line period and the accumulated error obtained by the superposition processing, and the second line period is transmitted, may specifically: in response to the accumulated error being greater than a threshold, the truncated second initial line period is corrected according to the accumulated error, to obtain the second line period; and in response to the accumulated error not being greater than the threshold, the truncated second initial line period is directly outputted as the second line period.

Further, the truncated second initial line period is corrected according to the accumulated error, to obtain the second line period, includes: an average value of the accumulated error is added to the truncated second initial line period, to obtain the second line period.

It should be noted that, step S2025 may be implemented in a software manner, may also be implemented in a hardware manner, and may also be implemented in a manner of combining software and hardware. In embodiments that need to be implemented in a hardware manner, the number of decimal places of the truncated decimal data is specifically decided according to the number of decimal places that can be stored in a hardware generation logic itself. That is, according to the number of decimal places that can be stored in the hardware generation logic, decimal places exceeding a decimal place part of the hardware generation logic are truncated, and superposition processing is performed by error accumulation, and a decimal part matching the hardware generation logic is outputted in an iteration manner. The truncation process may be implemented by hardware, and the accumulation process of the decimal part may be implemented by software, thereby achieving the object of software and hardware cooperation.

According to some other embodiments of the present disclosure, the first line period is inputted into the Kalman filter, so that the Kalman filter outputs the second initial line period, includes: the first line period is inputted into the Kalman filter, so that the Kalman filter predicts a system state according to the first line period, so as to obtain the second initial line period, and the system state is a clock period of two adjacent identical blanking identifiers in the data stream under the source clock, and the blanking identifier include at least one of a blanking start identifier and a blanking end identifier. In the present disclosure, the system state and the measurement value are respectively defined at two sides, i.e. the transmitting end and the receiving end of the display port, and the system state representing a line period of the transmitting end is estimated from a measurement value representing a line period of the receiving end by dynamic filtering, thereby further achieving a system state output which stably reflects the line period of the transmitting end.

Specifically, a specific process of constructing the Kalman filter and performing dynamic filtering by the Kalman filter may be as follows:
an initial state at time TO is defined as: Z=Z[0], X=X[0], H=h0, P=P[0], R=r0, and Q=q0. An initial value Z[0] of a measurement value Z represents the measurement value at time TO, for example, the number of line periods of a line clock between two adjacent BE intervals, the number of line periods of a line clock between two adjacent BS intervals, the number of line periods of a pixel clock between two adjacent BE intervals, and the number of line periods of a pixel clock between two adjacent BS intervals. An initial state X[0] of a system state X is selected, and here, an observation value of the system state may be selected, for example, an observation value of the system state at time T0, or another valid estimation value of the system state. An observation coefficient H, i.e. a ratio of the relationship between the measurement value and the system state, is selected, and is a constant h0. In terms of measurement, the measurement value may have a certain linear proportional relationship with the system state, and line periods of a plurality of pixel rows in an accumulated time period may be selected as the measurement value for calculation. For example, the system state calculated by selecting the BS intervals observed in 5 rows of line periods, is one fifth of the measurement value. Initial states q0 and r0 of error coefficients Q and R are selected, and the error coefficients are used to modify a calculation process of the Kalman filter, allowing a user to make adjustment according to an actual system, being able to remain unchanged after an initial state is selected. An initial value P[0] of an intermediate value P in the calculation process is selected, for example a state 0 is generally selected.

As shown in FIG. 4, the calculation is performed in an iterative manner, calculation is performed at each iteration time k, and a calculation result is to obtain a system state X at the iteration time k. An iteration interval is a measurement interval. The calculation process is as follows:
X[k]=X[k−1];
P[k]=P[k−1]+q0;
temp=(P[k]×h0/(P[k]×h0×h0+r0));
X[k]=X[k]+temp×(Z[k]−h0×X[k]);
P[k]=(1−temp×h0)×P[k].

Step S2021 of the present disclosure: the first line period is wrote into the first FIFO queue corresponding to the link, specifically includes: in response to a first interrupt being triggered, the first line period is wrote into the first FIFO queue corresponding to the link, and the first interrupt is ended, and the first interrupt carries an interrupt number generated according to the link and a serial number of the data stream; and the interruption number is used to represent the link corresponding to the first line period and the data stream, and is a unique number of the first line period. Step S2024 of the present disclosure: the second initial line period is read from the second FIFO queue, specifically includes: in response to a second interrupt being triggered, the second line period is read from the second FIFO queue according to a predetermined algorithm, and the second interrupt is ended, and the predetermined algorithm includes one of: a cyclic scheduling algorithm and a priority scheduling algorithm, and the second interrupt carries the interrupt number. By combining FIFO queues and interruption, the present disclosure can satisfy real-time processing requirements, and further increase the time sequence adjustment efficiency. Furthermore, by reading the second line period from the second FIFO queue by means of cyclic scheduling or priority scheduling, parallel cyclic iterations can be distributed to a plurality of threads, thereby further accelerating the time sequence adjustment progress of each link.

In addition, the specific implementation of step S2022, i.e. the first line period is read from the first FIFO queue is the same as the specific implementation of step S2024. The specific implementation of step S2023, i.e. the second initial line period is wrote into the corresponding second FIFO queue is the same as the specific implementation of step S2021, and will not be repeated herein.

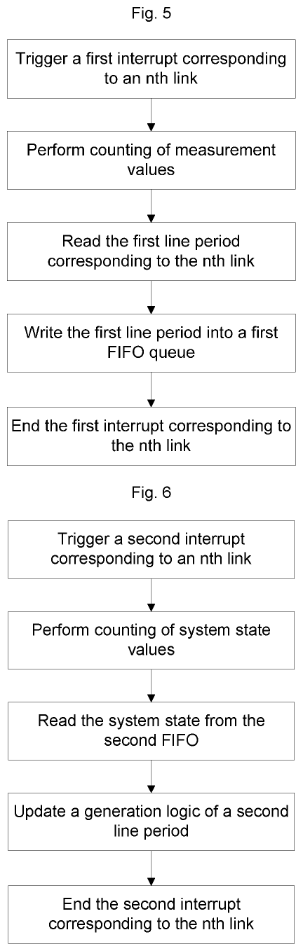

In some embodiments, as shown in FIG. 5, in response to a first line period of an nth link being obtained, a first interrupt corresponding to the nth link is triggered; counting of measurement values is performed; the first line period corresponding to the nth link is read and wrote into a first FIFO queue; and the first interrupt corresponding to the nth link is ended. As shown in FIG. 6, in response to a system state of an nth link being written into the second FIFO, a second interrupt corresponding to the nth link is triggered; counting of system state values is performed; the system state is read from the second FIFO, and a generation logic of a second line period is updated according to the system state, i.e. an output of the second line period is updated; and the second interrupt corresponding to the nth link is ended.

In a practical application process, the source clock is a line clock or a pixel clock, that is, the system state of the Kalman filter may be a clock period of two adjacent identical blanking identifier intervals under a clock domain of a line clock at the transmitting end, and may also be a clock period of two adjacent identical blanking identifier intervals under a clock domain of a pixel clock at the transmitting end. In order to further realize accurate adjustment of a clock time sequence of an output end corresponding to the two cases above, in still other optional embodiments of the present disclosure, in response to the source clock being the line clock, after the first line period is processed using the Kalman filtering algorithm to obtain the second line period, the method further includes: clock domain conversion is performed on the second line period, to obtain a line period of the first line period under a pixel clock. In response to the source clock being the pixel clock, before the first line period is processed using the Kalman filtering algorithm to obtain the second line period, the method further includes: clock domain conversion is performed on the first line period, to obtain the line period of the first line period under the pixel clock.

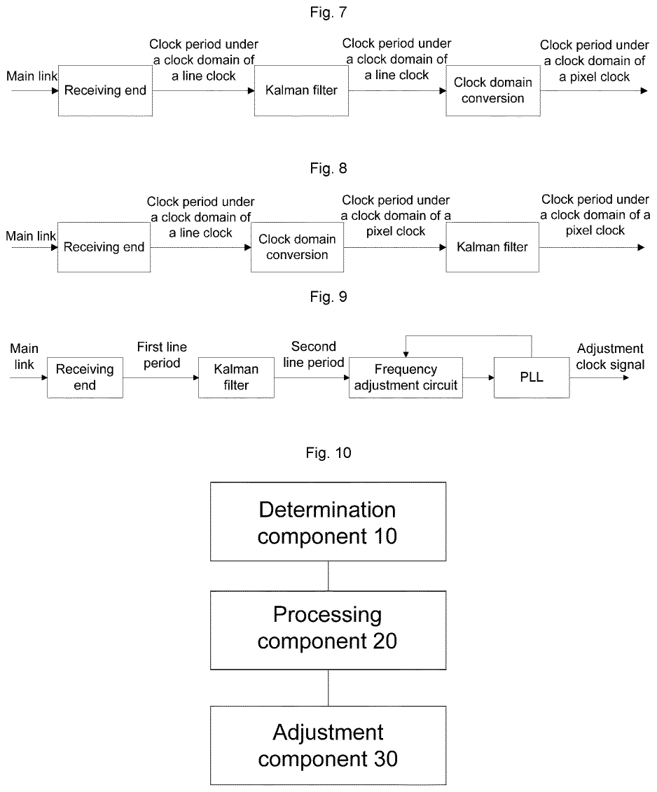

That is to say, as shown in FIG. 7, in the case where the system state is a clock period under a clock domain of a line clock of the transmitting end, the measurement value inputted by the Kalman filter at one side of the receiving end is a clock period of the image data under the clock domain of the line clock; the Kalman filter still outputs a clock period estimated under the clock domain of the line clock, which is then converted into a clock period under a clock domain of a pixel clock after cross-clock domain conversion. As shown in FIG. 8, in response to the system state being a clock period under a clock domain of a pixel clock of the transmitting end, a measurement value inputted by the Kalman filter at one side of the receiving end is a clock period of image data under the clock domain of the pixel clock, and is obtained after clock conversion of the clock domain of a line clock, and the Kalman filter outputs a clock period estimated under the clock domain of the pixel clock.

In order to further solve the problem that the clock frequency of the DP transmitting end does not match that of the DP receiving end, image data restored by the DP receiving end is distorted or even cannot be normally outputted, optionally, the output clock is adjusted according to the second line period includes: a dividing ratio is calculated according to the second line period and a reference clock period in a phase locked loop; and according to the dividing ratio, the phase locked loop (PPL for short) is controlled to generate a corresponding adjustment clock signal so as to restore at least one of: a phase of the output clock and a frequency of the output clock. By calculating a decimal dividing ratio between the second line period and a reference clock period in the phase locked loop, and then the PLL is controlled to generate the adjustment clock signal for restoration of image data according to the decimal dividing ratio, it is further ensured that the resolution of the restored image data is basically consistent with that of the transmitting end, and the accuracy and reliability of the restored image data are further ensured.

The present embodiment relates to a specific method for adjusting timing. As shown in FIG. 9, the method includes the following steps:
step S1: after a data stream is received from a main link of a transmitting end, the data stream is restored to obtain a clock period of two adjacent identical blanking identifiers which are observed from the main link, so as to obtain a first line period;
step S2: a Kalman filtering circuit is triggered to perform dynamic filtering calculation on the first line period, so as to obtain a standard clock period of two adjacent identical blanking identifiers at a transmitting end, and the standard clock period is taked as a second line period;
step S3: according to the second line period and in combination with a reference clock period in a PLL, a frequency adjustment circuit is controlled to perform frequency adjustment calculation, and a dynamically-changing frequency control decimal dividing ratio is outputted; and
step S4: according to the decimal dividing ratio, the PLL is controlled to generate an adjustment clock signal of a corresponding image pixel, for restoration use by image data, and the adjustment clock signal is fed back to the frequency adjustment circuit for dynamic adjustment reference.

It should be noted that the steps illustrated in the flowchart of the drawings can be executed in a computer system such as a set of computer-executable instructions, and although a logical order is shown in the flowchart, in some cases, the steps shown or described can be executed in a different order from that described herein.

Embodiments of the present disclosure further provide an apparatus for adjusting timing. It should be noted that, the apparatus for adjusting timing in the embodiments of the present disclosure can be used for executing the method for adjusting timing provided in embodiments of the present disclosure. The apparatus is configured to implement the embodiments and preferred embodiments, and what has been described will not be repeated again. As used below, the term “module” may implement a combination of software and/or hardware of predetermined functions. Although the apparatus described in the following embodiments is preferably implemented in software, implementation in hardware or a combination of software and hardware is also possible and could have been conceived.

Hereinafter, the apparatus for adjusting timing provided in embodiments of the present disclosure will be introduced.

FIG. 10 is a schematic diagram of an apparatus for adjusting timing according to embodiments of the present disclosure. As shown in FIG. 10, the apparatus includes:
a determination component 10, configured to in response to a data stream outputted by a transmitting end of a display port being received, determine a first line period according to the data stream, and the first line period is a line period of the data stream under an output clock, and the output clock is a clock domain of a receiving end of the display port;

Specifically, the line period is the time required for scanning one row of pixels, i.e. the number of pixels in one row, and is also referred to as a line length. Driven by the output clock, the receiving end samples a received signal to restore a pixel clock matching the clock of the transmitting end, thereby restoring accurate data. Generally, the receiving end samples the received signal at a rising edge or falling edge of the output clock. A clock domain of the receiving end is generally a line clock.
a processing component 20, configured to process the first line period at least using a Kalman filtering algorithm to obtain a second line period, and the second line period is a line period of the data stream under a source clock, and the source clock is a clock domain of the transmitting end; and
an adjustment component 30, configured to adjust the output clock according to the second line period.

By the embodiments, the determination component determines the first line period of the data stream under the output clock according to the data stream transmitted by the transmitting end of the display port; then the processing component processes the first line period at least using the Kalman filtering algorithm, to obtain the second line period of the data stream under the source clock; and the adjustment component adjusts the output clock according to the obtained second line period. Compared with the problem in the related art that the clock frequency of a DP transmitting end does not match that of a DP receiving end, image data restored by the DP receiving end is distorted or even cannot be normally outputted, in the present disclosure, according to the first line period, the second line period is predicted and estimated at least using the Kalman filtering algorithm, to obtain the second line period which stably reflects a pixel line length of the transmitting end, and then the estimated second line period is used to adjust the output clock, ensuring that the frequency of the adjusted output clock substantially matches the frequency of the source clock, thereby ensuring that image data restored according to the adjusted output clock is substantially consistent with original data, and avoiding the problem that the restored image data is distorted or even cannot be normally outputted.

In some optional embodiments, the determination component includes: a restoration module, configured to restore the data stream, to obtain image data and the output clock; an extraction module, configured to extract two adjacent identical blanking identifiers from the image data, and the blanking identifier include at least one of a blanking start identifier and a blanking end identifier; and a determination module, configured to determine a clock period of the two adjacent identical blanking identifiers under the output clock as the first line period.

In the embodiments, firstly the received data stream is restored to obtain the output clock and the image data including blanking identifiers, then the number of clock periods of two adjacent blanking start identifiers or two adjacent blanking end identifiers under the output clock is used to measure the line length of the image data, so as to obtain the first line period, which can obtain the first line period corresponding to the data stream more accurately, thereby providing more accurate data support for subsequent estimation of the second line period.

Specifically, the image data generally includes a BS identifier, a field blanking identifier, a timer value, a virtual display, a BE identifier, pixel data, a filling start identifier, filling data and a filling end identifier.

In some exemplary embodiments, the processing component includes: a processing module, configured to process the first line period using the Kalman filtering algorithm, to obtain a system state representing a clock period of two adjacent identical blanking identifiers in the data stream under the source clock, and the system state is the second line period.

Of course, in addition to the embodiments, a person skilled in the art may also use other manners to determine the second line period. In the present disclosure, the transmitting end outputs the data stream by at least one link, that is to say, the transmitting end transmits the data stream by a single-stream transport mode or a multi-stream transport mode, and one of the link corresponds to at least one first FIFO queue and at least one second FIFO queue, and the processing component includes:
a first writing module, configured to write the first line period into the first FIFO queue corresponding to the link according to the link corresponding to the first line period;
Specifically, the link corresponding to the first line period is a link for transmitting the data stream of the first line period. The first FIFO queue and the second FIFO queue may be hardware-designed FIFO or software-designed FIFO.
a first reading module, configured to in response to the first FIFO queue not being empty, read the first line period from the first FIFO queue, and input the first line period into a Kalman filter, so that the Kalman filter outputs a second initial line period, and the second initial line period is composed of the second line period and multiple pieces of decimal data;

Specifically, the Kalman filter is used for executing the Kalman filtering algorithm, and may be a hardware-designed device or a software-designed device; and the second initial line period is an original period value of the data stream under the source clock, the original period value being estimated by the Kalman filtering algorithm, and the second initial line period is a decimal number. The decimal data is a decimal data value of the second initial line period.
a second writing module, configured to write the second initial line period into the corresponding second FIFO queue;
a second reading module, configured to read the second initial line period from the second FIFO queue, and inputting the second initial line period into the Kalman filter for iterative calculation;

Specifically, the Kalman filtering algorithm is to obtain an optimal estimation value of a system state at the current moment of a dynamic system by a system state at a previous moment and a measurement value at the current moment; therefore, after the second initial line period is obtained, the second initial line period needs to be then fed back to an input end of the Kalman filter.
a truncation module, configured to truncate a part of the decimal data in the second initial line period and perform superposition processing on truncated decimal data, generate the second line period according to a truncated second initial line period and an accumulated error obtained by the superposition processing, and send the second line period.

Specifically, since the Kalman filtering algorithm is a cyclic iterative algorithm, the Kalman filtering algorithm performs truncation once every time when one second line period is obtained, and correspondingly obtains one piece of truncated decimal data, and obtains an accumulated error by performing superposition processing on these truncated decimal data.

In the embodiments, dynamic filtering is performed on the first line period by using the Kalman filtering algorithm, so that it can be further ensured that the second line period which stably reflects a pixel line length of a transmitting end is obtained, further achieving time sequence adjustment on a receiving end, thereby further ensuring that the restored image data at the receiving end is accurate and reliable. Furthermore, the Kalman filtering algorithm is an iterative algorithm, and needs to calculate a system state at the current moment according to a system state calculated at a previous moment and a measurement value at the current moment; therefore, in the present disclosure, by providing two stages of FIFO queues, the difference between a measurement value interval and a system state interval can be balanced, so that the two are basically the same, thereby further facilitating execution of the Kalman filtering algorithm. Furthermore, in the present disclosure, a first FIFO queue and a second FIFO queue are allocated for a transmission link of each data stream, so that a plurality of transmission links share Kalman filtering calculation resources, and data stream iterative calculation of various links is executed in a time division manner, so that the second line period corresponding to each link can be obtained, thereby avoiding the problem of resource waste caused by designing independent calculation resource for each link.

Of course, by providing the first FIFO queue and the second FIFO queue, the problem of losing multi-link data in an inputting and outputting process can also be prevented, and frequent bus operations can be avoided, thereby reducing the burden of a processor.

In order to further ensure the flexibility of time sequence adjustment, in an optional embodiment, the Kalman filter is a device for implementing the Kalman filtering algorithm, and the first FIFO queue and the second FIFO queue are software-implemented. Compared with a hardware-only implementation manner, the implementation manner of combining software and hardware in the present disclosure can provide the capability of programmable modification and updating a dynamic filtering algorithm in subsequent stages.

In addition, the truncation module may specifically include: a modification sub-module, configured to in response to the accumulated error being greater than a threshold, correct the truncated second initial line period according to the accumulated error, to obtain the second line period; and an output sub-module, configured to in response to the accumulated error not being greater than the threshold, directly output the truncated second initial line period as the second line period.

Further, the modification sub-module is further configured to add an average value of the accumulated error to the truncated second initial line period, to obtain the second line period.

It should be noted that, the truncation module may be implemented in a software manner, may also be implemented in a hardware manner, and may also be implemented in a manner of combining software and hardware. In embodiments that need to be implemented in a hardware manner, the number of decimal places of the truncated decimal data is specifically decided according to the number of decimal places that can be stored in a hardware generation logic itself. That is, according to the number of decimal places that can be stored in the hardware generation logic, decimal places exceeding a decimal place part of the hardware generation logic are truncated, and superposition processing is performed by error accumulation, and a decimal part matching the hardware generation logic is outputted in an iteration manner. The truncation process may be implemented by hardware, and the accumulation process of the decimal part may be implemented by software, thereby achieving the object of software and hardware cooperation.

According to some other embodiments of the present disclosure, the first reading module includes: an input sub-module, configured to input the first line period into the Kalman filter, so that the Kalman filter predicts a system state according to the first line period, so as to obtain the second initial line period, and the system state is a clock period of two adjacent identical blanking identifiers in the data stream under the source clock, and the blanking identifier include at least one of a blanking start identifier and a blanking end identifier. In the present disclosure, the system state and the measurement value are respectively defined at two sides, i.e. the transmitting end and the receiving end of the display port, and the system state representing a line period of the transmitting end is estimated from a measurement value representing a line period of the receiving end by dynamic filtering, thereby further achieving a system state output which stably reflects the line period of the transmitting end.

Specifically, a specific process of constructing the Kalman filter and performing dynamic filtering by the Kalman filter may be as follows:
an initial state at time TO is defined as: Z=Z[0], X=X[0], H=h0, P=P[0], R=r0, and Q=q0. An initial value Z[0] of a measurement value Z represents the measurement value at time TO, for example, the number of line periods of a line clock between two adjacent BE intervals, the number of line periods of a line clock between two adjacent BS intervals, the number of line periods of a pixel clock between two adjacent BE intervals, and the number of line periods of a pixel clock between two adjacent BS intervals. An initial state X[0] of a system state X is selected, and here, an observation value of the system state may be selected, for example, an observation value of the system state at time TO, or another valid estimation value of the system state. An observation coefficient H, i.e. a ratio of the relationship between the measurement value and the system state, is selected, and is a constant h0. In terms of measurement, the measurement value may have a certain linear proportional relationship with the system state, and line periods of a plurality of pixel rows in an accumulated time period may be selected as the measurement value for calculation. For example, the system state calculated by selecting the BS intervals observed in 5 rows of line periods, is one fifth of the measurement value. Initial states q0 and r0 of error coefficients Q and R are selected, and the error coefficients are used to modify a calculation process of the Kalman filter, allowing a user to make adjustment according to an actual system, being able to remain unchanged after an initial state is selected. An initial value P[0] of an intermediate value P in the calculation process is selected, for example a state 0 is generally selected.

The calculation is performed in an iterative manner, calculation is performed at each iteration time k, and a calculation result is to obtain a system state X at the iteration time k. An iteration interval is a measurement interval. The calculation process is as follows:

$$X [ k ] = X [ k - 1 ] ;$$

$$P [ k ] = P [ k - 1 ] + q 0 ;$$

$$temp = ( P [ k ] \times h0 / ( P [ k ] \times h 0 \times h 0 + r 0 ) ) ;$$

$$X [ k ] = X [ k ] + temp \times ( Z [ k ] - h 0 \times X [ k ] ) ;$$

$$P [ k ] = ( 1 - temp \times h 0 ) \times P [ k ] .$$

The first writing module of the present disclosure specifically includes: a writing sub-module, configured to in response to a first interrupt being triggered, write the first line period into the first FIFO queue corresponding to the link, and en the first interrupt, and the first interrupt carries an interrupt number generated according to the link and a serial number of the data stream; and the interruption number is used to represent the link corresponding to the first line period and the data stream, and is a unique number of the first line period. The second reading module in the present disclosure specifically includes: a reading sub-module, configured to in response to a second interrupt being triggered, read the second line period from the second FIFO queue according to a predetermined algorithm, and end the second interrupt, and the predetermined algorithm includes one of: a cyclic scheduling algorithm and a priority scheduling algorithm, and the second interrupt carries the interrupt number. By combining FIFO queues and interruption, the present disclosure can satisfy real-time processing requirements, and further increase the time sequence adjustment efficiency. Furthermore, by reading the second line period from the second FIFO queue by means of cyclic scheduling or priority scheduling, parallel cyclic iterations can be distributed to a plurality of threads, thereby further accelerating the time sequence adjustment progress of each link.

In addition, the specific implementation of the first reading module reading the first line period from the first FIFO queue is the same as the implementation of the second reading module; and the specific implementation of the second writing module writing the second initial line period into the corresponding second FIFO queue is the same as the specific implementation of the first writing module, and will not be repeated herein.

In some embodiments, as shown in FIG. 5, in response to a first line period of an nth link being obtained, a first interrupt corresponding to the nth link is triggered; counting of measurement values is performed; the first line period corresponding to the nth link is read and wrote into a first FIFO queue; and the first interrupt corresponding to the nth link is ended. As shown in FIG. 6, in response to a system state of an nth link being written into the second FIFO, a second interrupt corresponding to the nth link is triggered; counting of system state values is performed; the system state is read from the second FIFO, and a generation logic of a second line period is updated according to the system state, i.e. an output of the second line period is updated; and the second interrupt corresponding to the nth link is ended.

In a practical application process, the source clock is a line clock or a pixel clock, that is, the system state of the Kalman filter may be a clock period of two adjacent identical blanking identifier intervals under a clock domain of a line clock at the transmitting end, and may also be a clock period of two adjacent identical blanking identifier intervals under a clock domain of a pixel clock at the transmitting end. In order to further realize accurate adjustment of a clock time sequence of an output end corresponding to the two cases above, in some other optional embodiments of the present disclosure, the apparatus further includes: a first conversion component, configured to in response to the source clock being the line clock, after processing the first line period using the Kalman filtering algorithm to obtain the second line period, perform clock domain conversion on the second line period, to obtain a line period of the first line period under a pixel clock. The apparatus further includes: a second conversion component, configured to in response to the source clock being the pixel clock, before processing the first line period using the Kalman filtering algorithm to obtain the second line period, perform clock domain conversion on the first line period, to obtain the line period of the first line period under the pixel clock.

That is to say, as shown in FIG. 7, in the case where the system state is a clock period under a clock domain of a line clock of the transmitting end, the measurement value inputted by the Kalman filter at one side of the receiving end is a clock period of the image data under the clock domain of the line clock; the Kalman filter still outputs a clock period estimated under the clock domain of the line clock, which is then converted into a clock period under a clock domain of a pixel clock after cross-clock domain conversion. As shown in FIG. 8, in response to the system state being a clock period under a clock domain of a pixel clock of the transmitting end, a measurement value inputted by the Kalman filter at one side of the receiving end is a clock period of image data under the clock domain of the pixel clock, and is obtained after clock conversion of the clock domain of a line clock, and the Kalman filter outputs a clock period estimated under the clock domain of the pixel clock.

In order to further solve the problem that the clock frequency of the DP transmitting end does not match that of the DP receiving end, image data restored by the DP receiving end is distorted or even cannot be normally outputted, optionally, the output clock is adjusted according to the second line period includes: a dividing ratio is calculated according to the second line period and a reference clock period in a phase locked loop; and according to the dividing ratio, the phase locked loop (PPL for short) is controlled to generate a corresponding adjustment clock signal so as to restore at least one of: a phase of the output clock and a frequency of the output clock. By calculating a decimal dividing ratio between the second line period and a reference clock period in the phase locked loop, and then the PLL is controlled to generate the adjustment clock signal for restoration of image data according to the decimal dividing ratio, it is further ensured that the resolution of the restored image data is basically consistent with that of the transmitting end, and the accuracy and reliability of the restored image data are further ensured.

The apparatus for adjusting timing includes a processor and a memory; the determination component, the processing component and the adjustment component, etc. are all stored in the memory as program components, and the processor executes the program components stored in the memory to implement corresponding functions. The modules are all located in the same processor; or all the modules are located in different processors in any arbitrary combination manner.

The processor includes a kernel, and the kernel retrieves corresponding program components in the memory. One or more kernels may be provided, and kernel parameters are adjusted to at least solve the problem in the related art that image data restored by a DP receiving end is distorted or even cannot be normally outputted.

The memory may include forms such as a non-permanent memory, a random access memory (RAM) and/or a non-volatile memory in a computer-readable medium, for example, a read-only memory (ROM) or a flash memory (flash RAM), and the memory includes at least one memory chip.

Embodiments of the present disclosure provide a non-transitory computer-readable storage medium, the non-transitory computer-readable storage medium includes a program stored therein, and when the program runs, a device where the non-transitory computer-readable storage medium is located is controlled to execute the method for adjusting timing.

Specifically, the method for adjusting timing includes:
Step S201, in response to a data stream outputted by a transmitting end of a display port being received, a first line period is determined according to the data stream, and the first line period is a line period of the data stream under an output clock, and the output clock is a clock domain of a receiving end of the display port;
Specifically, the line period is the time required for scanning one row of pixels, i.e. the number of pixels in one row, and is also referred to as a line length. Driven by the output clock, the receiving end samples a received signal to restore a pixel clock matching the clock of the transmitting end, thereby restoring accurate data. Generally, the receiving end samples the received signal at a rising edge or falling edge of the output clock. A clock domain of the receiving end is generally a line clock.

step S202, the first line period is processed at least using a Kalman filtering algorithm to obtain a second line period, and the second line period is a line period of the data stream under a source clock, and the source clock is a clock domain of the transmitting end;

Specifically, the clock domain of the source clock is usually a main link domain.

step S203, the output clock is adjusted according to the second line period.

Optionally, the first line period is determined according to the data stream includes: the data stream is restored, to obtain image data and the output clock; two adjacent identical blanking identifiers are extracted from the image data, and the blanking identifier include at least one of a blanking start identifier and a blanking end identifier; and it is determined that a clock period of the two adjacent identical blanking identifiers under the output clock as the first line period.

Optionally, the transmitting end outputs the data stream by at least one link, one of the link corresponds to at least one first FIFO queue and at least one second FIFO queue, and the first line period is processed at least using the Kalman filtering algorithm to obtain the second line period, include: the first line period is wrote into the first FIFO queue corresponding to the link according to the link corresponding to the first line period; in response to the first FIFO queue not being empty, the first line period is read from the first FIFO queue, and the first line period is inputted into a Kalman filter, so that the Kalman filter outputs a second initial line period, and the second initial line period is composed of the second line period and multiple pieces of decimal data; the second initial line period is wrote into the corresponding second FIFO queue; the second initial line period is read from the second FIFO queue, and the second initial line period is inputted into the Kalman filter for iterative calculation; and a part of the multiple pieces of decimal data in the second initial line period is truncated and superposition processing is performed on truncated decimal data, the second line period is generated according to the truncated second initial line period and an accumulated error obtained by the superposition processing, and the second line period is transmitted.

Optionally, the first line period is inputted into the Kalman filter, so that the Kalman filter outputs the second initial line period, includes: the first line period is inputted into the Kalman filter, so that the Kalman filter predicts a system state according to the first line period, so as to obtain the second initial line period, and the system state is a clock period of two adjacent identical blanking identifiers in the data stream under the source clock, and the blanking identifier include at least one of a blanking start identifier and a blanking end identifier.

Optionally, the first line period is wrote into the first FIFO queue corresponding to the link, includes: in response to a first interrupt being triggered, the first line period is wrote into the first FIFO queue corresponding to the link, and the first interrupt is ended, and the first interrupt carries an interrupt number generated according to the link and a serial number of the data stream; and the second initial line period is read from the second FIFO queue, includes: in response to a second interrupt being triggered, the second line period is read from the second FIFO queue according to a predetermined algorithm, and the second interrupt is ended, and the predetermined algorithm includes one of: a cyclic scheduling algorithm and a priority scheduling algorithm, and the second interrupt carries the interrupt number.

Optionally, the source clock is a line clock or a pixel clock, and in response to the source clock being the line clock, after the first line period is processed at least using the Kalman filtering algorithm to obtain the second line period, the method further includes: clock domain conversion is performed on the second line period, to obtain a line period of the first line period under a pixel clock; and in response to the source clock being the pixel clock, before the first line period is processed at least using the Kalman filtering algorithm to obtain the second line period, the method further includes: clock domain conversion is performed on the first line period, to obtain the line period of the first line period under the pixel clock.

Optionally, the output clock is adjusted according to the second line period includes: a dividing ratio is calculated according to the second line period and a reference clock period in a phase locked loop; and according to the dividing ratio, the phase locked loop is controlled to generate a corresponding adjustment clock signal so as to restore at least one of: a phase of the output clock and a frequency of the output clock.

Embodiments of the present disclosure provide a processor, the processor being configured to run a program, and the program runs to execute the method for adjusting timing.

Embodiments of the present disclosure provide a device, the device including a processor, a memory and a program which is stored in the memory and can run on the processor, and when the processor executes the program, the following steps are implemented:
step S201, in response to a data stream outputted by a transmitting end of a display port being received, a first line period is determined according to the data stream, and the first line period is a line period of the data stream under an output clock, and the output clock is a clock domain of a receiving end of the display port;
step S202, the first line period is processed at least using a Kalman filtering algorithm to obtain a second line period, and the second line period is a line period of the data stream under a source clock, and the source clock is a clock domain of the transmitting end; and
step S203: the output clock is adjusted according to the second line period.

The device herein may be a server, a PC, a PAD, a mobile phone, etc.

The device may specifically be an image adapter or a docking station that includes a display port.

The present disclosure further provides a computer program product, which, when executed on a data processing device, is suitable for executing a program in which the following method steps are initialized:
step S201, in response to a data stream outputted by a transmitting end of a display port being received, a first line period is determined according to the data stream, and the first line period is a line period of the data stream under an output clock, and the output clock is a clock domain of a receiving end of the display port;
step S202, the first line period is processed at least using a Kalman filtering algorithm to obtain a second line period, and the second line period is a line period of the data stream under a source clock, and the source clock is a clock domain of the transmitting end; and
step S203: the output clock is adjusted according to the second line period.

It is apparent that a person skilled in the art shall understand that all of the described modules or steps in the present disclosure may be implemented by using a general computation apparatus, may be centralized on a single computation apparatus or may be distributed on a network composed of multiple computation apparatuses, and may be implemented by using executable program codes of the computation apparatus. Thus, the described modules or steps may be stored in a storage apparatus and executed by the computation apparatus. In addition, in some cases, the shown or described steps may be executed in a sequence different from that shown herein, or they are manufactured into integrated circuit modules, or multiple modules or steps therein are manufactured into a single integrated circuit module. Thus, the present disclosure is not limited to any specific hardware and software combinations.

A person skilled in the art should understand that the embodiments of the present disclosure can be provided as a method, a system or a computer program product. Therefore, the present disclosure may take the form of entirely hardware embodiments, entirely software embodiments or embodiments combining software and hardware. Furthermore, the present disclosure may take the form of a computer program product implemented on one or more computer-usable storage media (including but not limited to a disk memory, a CD-ROM, an optical memory, etc.) containing computer-usable program codes.

The present disclosure is described with reference to the flowcharts and/or block diagrams of the method, device (system), and computer program product according to the embodiments of the present disclosure. It should be understood that computer program instructions may be used to implement each process and/or block in the flowchart and/or block diagram and a combination of processes and/or blocks in the flowchart and/or the block diagram. These computer program instructions can be provided to a general-purpose computer, a special-purpose computer, an embedded processor, or a processor of other programmable data processing devices to generate a machine, so that instructions executed by a processor of a computer or other programmable data processing devices generate an apparatus for realizing a designated function in one or more flows in a flowchart and/or in one or more blocks in a block diagram.

These computer program instructions can also be stored in a computer-readable memory that can direct a computer or other programmable data processing devices to operate in a particular manner, such that the instructions stored in the computer-readable memory produce a manufacture including an instruction apparatus, the instruction apparatus implementing functions specified in one or more flows of a flowchart and/or one or more blocks of a block diagram.

These computer program instructions may also be loaded onto a computer or other programmable data processing devices, so that a series of operation steps are executed on the computer or other programmable devices to generate processing implemented by the computer, so that the instructions executed on the computer or other programmable data processing devices provide steps for implementing functions specified in one or more flows in the flowchart and/or one or more blocks in the block diagram.

In a typical configuration, a computing device includes one or more processors (CPU), an input/output interface, a network interface, and a memory.

The memory may include forms such as a non-permanent memory, a random access memory (RAM), and/or a non-transitory memory, such as a read-only memory (ROM) or a flash RAM, in a computer-readable medium. The memory is an example of a computer-readable medium.

The computer-readable medium, including both permanent and non-permanent, and removable and non-removable medium, may achieve information storage by any method or technique. The information may be computer-readable instructions, data structures, modules of a program, or other data. Examples of the computer storage medium include but are not limited to, phase change memory (PRAM), static random-access memory (SRAM), dynamic random-access memory (DRAM), other types of random-access memories (RAM), read-only memory (ROM), electrically erasable programmable read-only memory (EEPROM), flash memory or other memory technique, compact disc read-only memory (CD-ROM), digital versatile disc (DVD) or other optical storage, magnetic cassettes, magnetic tape magnetic disk storage or other magnetic storage devices, or any other non-transmission media, which may be used to store information that may be accessed by the computing device. As defined herein, the computer-readable media do not include transitory computer-readable media, such as modulated data signals and carriers.

It should also be noted that the terms “include”, “include”, or any other variations thereof are intended to cover a non-exclusive inclusion, so that a process, method, commodity or device that includes a series of elements not only includes those elements, but also includes other elements that are not explicitly listed, or further includes inherent elements of the process, method, commodity, or device. Without further limitation, an element defined by a sentence “include a . . . ” does not exclude other same elements existing in the process, method, commodity, or device that includes the element.

From the description above, it can be determined that the embodiments of the present disclosure achieve the following technical effects:

1) In the method for adjusting timing of the present disclosure, firstly according to the data stream transmitted by the transmitting end of the display port, the first line period of the data stream under the output clock is determined; then the first line period is processed at least using the Kalman filtering algorithm, to obtain the second line period of the data stream under the source clock; and finally, the output clock is adjusted according to the obtained second line period. Compared with the problem in the related art that the clock frequency of a DP transmitting end does not match that of a DP receiving end, image data restored by the DP receiving end is distorted or even cannot be normally outputted, in the present disclosure, according to the first line period, the second line period is predicted and estimated at least using the Kalman filtering algorithm, to obtain the second line period which stably reflects a pixel line length of the transmitting end, and then the estimated second line period is used to adjust the output clock, ensuring that the frequency of the adjusted output clock substantially matches the frequency of the source clock, thereby ensuring that image data restored according to the adjusted output clock is substantially consistent with original data, and avoiding the problem that the restored image data is distorted or even cannot be normally outputted.

2) In the apparatus for adjusting timing of the present disclosure, the determination component determines the first line period of the data stream under the output clock according to the data stream transmitted by the transmitting end of the display port; then the processing component processes the first line period at least using the Kalman filtering algorithm, to obtain the second line period of the data stream under the source clock; and the adjustment component adjusts the output clock according to the obtained second line period. Compared with the problem in the related art that the clock frequency of a DP transmitting end does not match that of a DP receiving end, image data restored by the DP receiving end is distorted or even cannot be normally outputted, in the present disclosure, according to the first line period, the second line period is predicted and estimated at least using the Kalman filtering algorithm, to obtain the second line period which stably reflects a pixel line length of the transmitting end, and then the estimated second line period is used to adjust the output clock, ensuring that the frequency of the adjusted output clock substantially matches the frequency of the source clock, thereby ensuring that image data restored according to the adjusted output clock is substantially consistent with original data, and avoiding the problem that the restored image data is distorted or even cannot be normally outputted.

The content above merely relates to preferred embodiments of the present disclosure, and is not intended to limit the present disclosure. For a person skilled in the art, the present disclosure may have various modifications and changes. Any modifications, equivalent replacements, improvements and the like made within the spirit and principle of the present disclosure shall all fall within the scope of protection of the present disclosure.

1. A method for adjusting timing, comprising:
in response to a data stream outputted by a transmitting end of a display port being received, determining a first line period according to the data stream, wherein the first line period is a line period of the data stream under an output clock, and the output clock is a clock domain of a receiving end of the display port;
processing the first line period at least using a Kalman filtering algorithm to obtain a second line period, wherein the second line period is a line period of the data stream under a source clock, and the source clock is a clock domain of the transmitting end; and
adjusting the output clock according to the second line period.

2. The method as claimed in claim 1, wherein determining the first line period according to the data stream comprises:
restoring the data stream, to obtain image data and the output clock;
extracting two adjacent identical blanking identifiers from the image data, wherein the blanking identifier comprise at least one of a blanking start identifier and a blanking end identifier; and
determining a clock period of the two adjacent identical blanking identifiers under the output clock as the first line period.

3. The method as claimed in claim 1, wherein the transmitting end outputs the data stream by at least one link, one of the link corresponds to at least one first First Input First Output (FIFO) queue and at least one second FIFO queue, and processing the first line period at least using the Kalman filtering algorithm to obtain the second line period, comprise:
writing the first line period into the first FIFO queue corresponding to the link according to the link corresponding to the first line period;
in response to the first FIFO queue not being empty, reading the first line period from the first FIFO queue, and inputting the first line period into a Kalman filter, so that the Kalman filter outputs a second initial line period, wherein the second initial line period is composed of the second line period and multiple pieces of decimal data;
writing the second initial line period into the corresponding second FIFO queue;
reading the second initial line period from the second FIFO queue, and inputting the second initial line period into the Kalman filter for iterative calculation; and
truncating a part of the multiple pieces of decimal data in the second initial line period and performing superposition processing on truncated decimal data, generating the second line period according to a truncated second initial line period and an accumulated error obtained by the superposition processing, and transmitting the second line period.

4. The method as claimed in claim 3, wherein inputting the first line period into the Kalman filter, so that the Kalman filter outputs the second initial line period, comprises:
inputting the first line period into the Kalman filter, so that the Kalman filter predicts a system state according to the first line period, so as to obtain the second initial line period, wherein the system state is a clock period of two adjacent identical blanking identifiers in the data stream under the source clock, and the blanking identifier comprise at least one of a blanking start identifier and a blanking end identifier.

5. The method as claimed in claim 3, wherein
writing the first line period into the first FIFO queue corresponding to the link, comprises: in response to a first interrupt being triggered, writing the first line period into the first FIFO queue corresponding to the link, and ending the first interrupt, wherein the first interrupt carries an interrupt number generated according to the link and a serial number of the data stream; and
reading the second initial line period from the second FIFO queue, comprises: in response to a second interrupt being triggered, reading the second line period from the second FIFO queue according to a predetermined algorithm, and ending the second interrupt, wherein the predetermined algorithm comprises one of: a cyclic scheduling algorithm and a priority scheduling algorithm, and the second interrupt carries the interrupt number.

6. The method as claimed in claim 1, wherein the source clock is a line clock or a pixel clock,
in response to the source clock being the line clock, after processing the first line period at least using the Kalman filtering algorithm to obtain the second line period, the method further comprises: performing clock domain conversion on the second line period, to obtain a line period of the first line period under a pixel clock; and
in response to the source clock being the pixel clock, before processing the first line period at least using the Kalman filtering algorithm to obtain the second line period, the method further comprises: performing clock domain conversion on the first line period, to obtain the line period of the first line period under the pixel clock.

7. The method as claimed in claim 1, wherein adjusting the output clock according to the second line period comprises:
calculating a dividing ratio according to the second line period and a reference clock period in a phase locked loop; and
according to the dividing ratio, controlling the phase locked loop to generate a corresponding adjustment clock signal so as to restore at least one of: a phase of the output clock and a frequency of the output clock.

8. (canceled)

9. A non-transitory computer-readable storage medium, wherein the non-transitory computer medium comprises a program stored therein, wherein when the program runs, cause a device where the non-transitory computer-readable storage medium is located to:
In response to a data s putted by a transmitting end of a display port being received, determine a first line period according the data stream, wherein the first line period is a line period of the data stream under an output clock, and the output clock is a clock domain of a receiving end of the display port;
process the first line period at least using a Kalman filtering algorithm to obtain a second line period, wherein the second line period is a line period of the data stream under a source clock, and the source clock is a clock domain of the transmitting end; and
adjust the output clock according to the second line period.

10. An electronic device, comprising: one or more processors, a memory and one or more programs, wherein the one or more programs are stored in the memory and configured to be executed by the one or more processors, and the one or more programs comprise instructions, the instructions, when being executed by the one or more processors cause the one or more processors to:
In response to a data stream outputted by a transmitting end of a display port being received, determine a first line period according to the data stream, wherein the first period is a line period of the data stream under an output clock, and the output clock is a clock domain of a receiving end of the display port;
process the first line period at least using a Kalman filtering algorithm to obtain a second line period, wherein the second line period is a line period of the data stream under a source clock, and the source clock is a clock domain of the transmitting end; and
adjust the output clock according to the second line period.

11. The method as claimed in claim 3, wherein generating the second line period according to the truncated second initial line period and the accumulated error obtained by the superposition processing, and transmitting the second line period comprises:
in response to the accumulated error being greater than a threshold, correcting the truncated second initial line period according to the accumulated error, to obtain the second line period; and
in response to the accumulated error not being greater than the threshold, directly outputting the truncated second initial line period as the second line period.

12. The method as claimed in claim 11, wherein correcting the truncated second initial line period according to the accumulated error, to obtain the second line period, comprises:
adding an average value of the accumulated error to the truncated second initial line period, to obtain the second line period.

13. The non-transitory computer-readable storage medium as claimed in claim 9, wherein when the program runs, cause the device further to:
restore the data stream, to obtain image data and the output clock;
extract two adjacent identical blanking identifiers from the image data, wherein the blanking identifier comprise at least one of a blanking start identifier and a blanking end identifier; and
determine a clock period of the two adjacent identical blanking identifiers under the output clock as the first line period.

14. The non-transitory computer-readable storage medium as claimed in claim 9, wherein the transmitting end outputs the data stream by at least one link, one of the link corresponds to at least one first FIFO queue and at least one second FIFO queue, when the program runs, cause the device further to:
write the first line period into the first FIFO queue corresponding to the link according to the link corresponding to the first line period;
in response to the first FIFO queue not being empty, read the first line period from the first FIFO queue, and inputting the first line period into a Kalman filter, so that the Kalman filter outputs a second initial line period, wherein the second initial line period is composed of the second line period and multiple pieces of decimal data;
write the second initial line period into the corresponding second FIFO queue;
read the second initial line period from the second FIFO queue, and input the second initial line period into the Kalman filter for iterative calculation; and
truncate a part of the multiple pieces of decimal data in the second initial line period and perform superposition processing on truncated decimal data, generate the second line period according to a truncated second initial line period and an accumulated error obtained by the superposition processing, and transmit the second line period.

15. The non-transitory computer-readable storage medium as claimed in claim 14, wherein when the program runs, cause the device further to:
input the first line period into the Kalman filter, so that the Kalman filter predicts a system state according to the first line period, so as to obtain the second initial line period, wherein the system state is a clock period of two adjacent identical blanking identifiers in the data stream under the source clock, and the blanking identifier comprise at least one of a blanking start identifier and a blanking end identifier.

16. The non-transitory computer-readable storage medium as claimed in claim 14, wherein when the program runs, cause the device further to:
in response to a first interrupt being triggered, write the first line period into the first FIFO queue corresponding to the link, and end the first interrupt, wherein the first interrupt carries an interrupt number generated according to the link and a serial number of the data stream; and
in response to a second interrupt being triggered, read the second line period from the second FIFO queue according to a predetermined algorithm, and end the second interrupt, wherein the predetermined algorithm comprises one of: a cyclic scheduling algorithm and a priority scheduling algorithm, and the second interrupt carries the interrupt number.

17. The non-transitory computer-readable storage medium as claimed in claim 9, wherein the source clock is a line clock or a pixel clock, when the program runs, cause the device further to:
in response to the source clock being the line clock, after processing the first line period at least using the Kalman filtering algorithm to obtain the second line period, perform clock domain conversion on the second line period, to obtain a line period of the first line period under a pixel clock; and
in response to the source clock being the pixel clock, before processing the first line period at least using the Kalman filtering algorithm to obtain the second line period, perform clock domain conversion on the first line period, to obtain the line period of the first line period under the pixel clock.

18. The non-transitory computer-readable storage medium as claimed in claim 9, wherein when the program runs, cause the device further to:
calculate a dividing ratio according to the second line period and a reference clock period in a phase locked loop; and
according to the dividing ratio, control the phase locked loop to generate a corresponding adjustment clock signal so as to restore at least one of: a phase of the output clock and a frequency of the output clock.

19. The electronic device as claimed in claim 10, wherein the instructions, when being executed by the one or more processors, cause the one or more processors further to:
restore the data stream, to obtain image data and the output clock;
extract two adjacent identical blanking identifiers from the image data, wherein the blanking identifier comprise at least one of a blanking start identifier and a blanking end identifier; and
determine a clock period of the two adjacent identical blanking identifiers under the output clock as the first line period.

20. The electronic device as claimed in claim 10, wherein the transmitting end outputs the data stream by at least one link, one of the link corresponds to at least one first FIFO queue and at least one second FIFO queue, the instructions, when being executed by the one or more processors, cause the one or more processors further to:
write the first line period into the first FIFO queue corresponding to the link according to the link corresponding to the first line period;
in response to the first FIFO queue not being empty, read the first line period from the first FIFO queue, and inputting the first line period into a Kalman filter, so that the Kalman filter outputs a second initial line period, wherein the second initial line period is composed of the second line period and multiple pieces of decimal data;
write the second initial line period into the corresponding second FIFO queue;
read the second initial line period from the second FIFO queue, and input the second initial line period into the Kalman filter for iterative calculation; and
truncate a part of the multiple pieces of decimal data in the second initial line period and perform superposition processing on truncated decimal data, generate the second line period according to a truncated second initial line period and an accumulated error obtained by the superposition processing, and transmit the second line period.

21. The electronic device as claimed in claim 20, wherein the instructions, when being executed by the one or more processors, cause the one or more processors further to:
input the first line period into the Kalman filter, so that the Kalman filter predicts a system state according to the first line period, so as to obtain the second initial line period, wherein the system state is a clock period of two adjacent identical blanking identifiers in the data stream under the source clock, and the blanking identifier comprise at least one of a blanking start identifier and a blanking end identifier.
